(19) United States
(12) Patent Application Publication
(10) Pub. No.: US 2025/0246560 A1
(43) Pub. Date: Jul. 31, 2025

(54) RADIO FREQUENCY LEADS HAVING REDUCED LINE WIDTH

(71) Applicant: Qorvo US, Inc., Greensboro, NC (US)

(72) Inventor: Matthew Tyler Irvine, Garland, TX (US)

(21) Appl. No.: 19/033,067

(22) Filed: Jan. 21, 2025

Related U.S. Application Data
(60) Provisional application No. 63/626,103, filed on Jan. 29, 2024.

(51) Int. Cl. H01L 23/66; H01L 23/495

(52) U.S. Cl. CPC H01L 23/66; H01L 23/49513; H01L 23/49517

(57) ABSTRACT

According to some aspects, a semiconductor device is disclosed. The semiconductor device includes a semiconductor package comprising a trace, a leadframe comprising a lead, and a lead attach material. The lead may include a base and an opposing surface opposite the base. The width of the base may be narrower than a width of the opposing surface along a length of the lead. The lead attach material may be positioned on the base along the length and is configured to connect the lead to the trace.

### CROSS-REFERENCE TO RELATED APPLICATIONS

The present application claims the benefit of U.S. Provisional App. No. 63/626,103, entitled “Radio Frequency Leads Having Reduced Line Width” and filed on Jan. 29, 2024, which is hereby incorporated by reference in its entirety.

The present application is related to co-pending application Ser. No. 18/218,670, entitled “Circuit Package with Improved Thermal Management,” filed on Jul. 6, 2023, which is hereby incorporated herein by reference in its entirety.

### TECHNICAL FIELD

The present disclosure relates generally to package interconnects, and more specifically to interconnects that are capable of operating at increased radio frequencies while providing for robust electrical currents.

### BACKGROUND

As radio frequency (RF) operating points increase, semiconductor packaging demands likewise become more complex. For example, as frequency operating points increase, it is desirable for lead and trace sizes to decrease in order to maintain desirable operating values, such as impedance values. One issue with some leaded semiconductor device packages is that RF traces leading to package interconnects are getting sufficiently small that conventional RF leads may be too large to be attached to the trace. In some package constructions, it is desirable for a metal pad on a package to be wider than a corresponding lead to accommodate tolerances when forming a connection (e.g., through soldering), and these considerations push RF leads to be smaller and smaller. On the other hand, a wider lead is desirable to accommodate sufficient current values. To handle a wider lead that can accommodate desirable values of electrical current, it is desirable to develop solutions and configurations to allow sufficiently wide leads to attach to narrow traces. Thus, there remains a need for effective ways to configure leads such that they are sufficiently narrow for connecting to package traces while being sufficiently wide to accommodate device currents.

### SUMMARY

Embodiments of the present disclosure include systems, devices, and methods of.

In an exemplary aspect, a semiconductor device is disclosed. The semiconductor device includes a semiconductor package comprising a trace, a leadframe comprising a lead, and a lead attach material. The lead may include a base and an opposing surface opposite the base. The width of the base may be narrower than a width of the opposing surface along a length of the lead. The lead attach material may be positioned on the base along the length and is configured to connect the lead to the trace.

In another exemplary aspect, an integrated circuit device for wireless communications is disclosed. The integrated circuit device may include a package that includes an integrated circuit and a trace. The integrated circuit device may further include a frame comprising a lead, wherein the lead comprises a base, a surface opposite the base, and a portion whose length along a longitudinal axis is less than the length of the lead. The integrated circuit device may further include a solder material. According to some aspects, a width of the base may be smaller than a width of the surface opposite the base along the portion, and the lead may be electrically connected to the trace via the solder material.

In another exemplary aspect, a system is disclosed. The system may include a circuit board; and a device connected to the circuit board. The device may include an electronic package comprising a trace; a leadframe comprising a lead; and a lead attach material. The lead may include a base and an opposing surface opposite the base. A width of the base may be narrower than a width of the opposing surface along a length of the lead. The lead attach material may be positioned on the base along the length and is configured to connect the lead to the trace

Additional aspects, features, and advantages of the present disclosure will become apparent from the following detailed description.

### BRIEF DESCRIPTION OF THE DRAWINGS

The accompanying drawing figures incorporated in and forming a part of this specification illustrate several aspects of the disclosure, and together with the description, serve to explain the principles of the disclosure.

FIG. 1A is a simplified overhead view of an exemplary semiconductor device, according to aspects of the present disclosure.

FIG. 1B is a simplified overhead view of an exemplary leadframe, according to aspects of the present disclosure.

FIG. 2 is a simplified overhead view of an exemplary semiconductor device at a stage of manufacture, according to aspects of the present disclosure.

FIG. 3 is a more detailed partial perspective view of a device, according to aspects of the present disclosure.

FIG. 4 is a more detailed partial perspective view of a device that may be configured for higher radio frequencies than FIG. 3, according to aspects of the present disclosure.

FIG. 5 is an even more detailed partial perspective view of a device from FIG. 4, representing the window as shown in FIG. 4 at a stage of manufacture, according to aspects of the present disclosure.

FIG. 6 illustrates two views of leadframe leads, according to aspects of the present disclosure.

FIGS. 7A-7C are cross-sectional views of different leadframe leads along a length of attachment to package traces, according to aspects of the present disclosure.

FIG. 8 is an example system, according to aspects of the present disclosure.

### DETAILED DESCRIPTION

For the purposes of promoting an understanding of the principles of the present disclosure, reference will now be made to the embodiments illustrated in the drawings, and specific language will be used to describe the same. It is nevertheless understood that no limitation to the scope of the disclosure is intended. Any alterations and further modifications to the described devices, systems, and methods, and any further application of the principles of the present disclosure are fully contemplated and included within the present disclosure as would normally occur to one skilled in the art to which the disclosure relates. In particular, it is fully contemplated that the features, components, and/or steps described with respect to one embodiment may be combined with the features, components, and/or steps described with respect to other embodiments of the present disclosure. For the sake of brevity, however, the numerous iterations of these combinations will not be described separately. Moreover, terms of orientation, such as “top,” “bottom,” “underneath,” “overhead,” “underside,” etc. as used herein, are used to refer to relative positions of an object as oriented in a figure, and, as would be understood in the art, do not imply any particular orientation of the object in use and are intended to encompass different orientations of the object in use.

Exemplary embodiments of electronic devices are presented herein. In some embodiments, one or more leads are configured to carry radio frequency signals of increasing frequency while at the same time being capable of supporting robust current flows. In some embodiments, portions of a lead are etched away, leaving a narrower base for electrical connection to traces of an electronic package residing below a wider opposing surface of the lead.

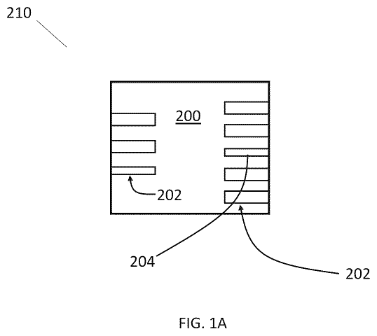

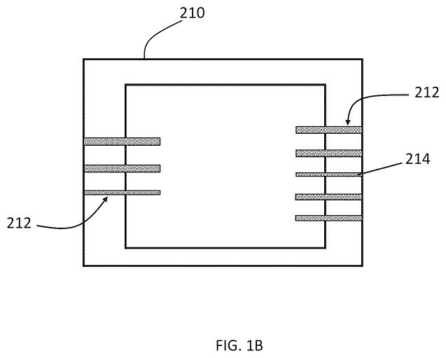

FIG. 1A is a simplified overhead view of an exemplary semiconductor device 201, according to aspects of the present disclosure. In this example, the device 201 includes a package 200 (e.g., also referred to as an electronic package or integrated circuit package) and package traces 202. The package 200 may house one or more integrated circuits (not shown), at least one of which may transmit and/or receive RF signals on at least one of the package traces, such as exemplary trace 204. The traces 202 are generally configured to carry signals into or out of the package 200. There may be greater or fewer traces than shown, according to the application. Exemplary integrated circuits housed in the package are radio frequency circuits for communication, amplifiers such as power amplifiers, baseband processors, filters and/or other known circuitry for generating or receiving wireless signals. The device 201 represents an example device to which the techniques described herein for configuring traces can be applied.

FIG. 1B is a simplified overhead view of an exemplary leadframe 210, according to aspects of the present disclosure. The leadframe 210 is configured to provide interconnections for a package, such as package 200. The leadframe 210 includes leadframe leads 212 as shown. In practice, there may be greater or fewer leadframe leads than shown, and the leads may be placed on any side of the leadframe 210, according to the desired configuration and application. An exemplary lead is labeled as 214. The leadframe leads 212 are generally configured to carry signals into or out of an associated package. Although the leadframe 210 in this embodiment has two portions 215 and 216, the leadframe 210 may instead be constructed as a single unit.

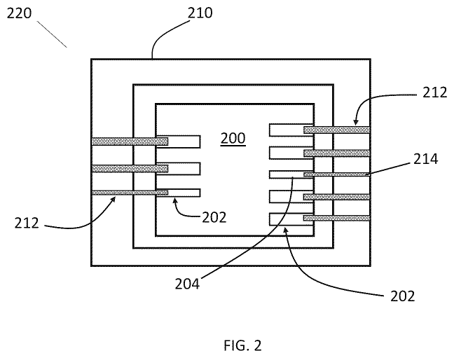

FIG. 2 is a simplified overhead view of an exemplary semiconductor device 220 at a stage of manufacture, according to aspects of the present disclosure. As shown, the device 220 includes a semiconductor package 200 electrically connected to a leadframe portions 215 and 216 (and therefore to leadframe 210). The device 220 includes package traces 202, and the leadframe 210 includes leadframe leads 212. An exemplary one of the package traces 204 is shown connected to an exemplary leadframe lead 214. Aspects of the current disclosure apply to the interconnection of leadframe leads (such as leads 212) and package traces (such as traces 204) for carrying radio frequency signals, such as signals have a frequency between 50 MHz and 60 GHz and used in wireless communication. Traces and leads as disclosed herein may be made of any known conductive material, such as conductive metals or alloys, examples of which are copper or copper alloys. The packages described herein, such as package 200, may include a die or integrated circuit, such as for high-power radar applications or other applications involving radio frequency signals.

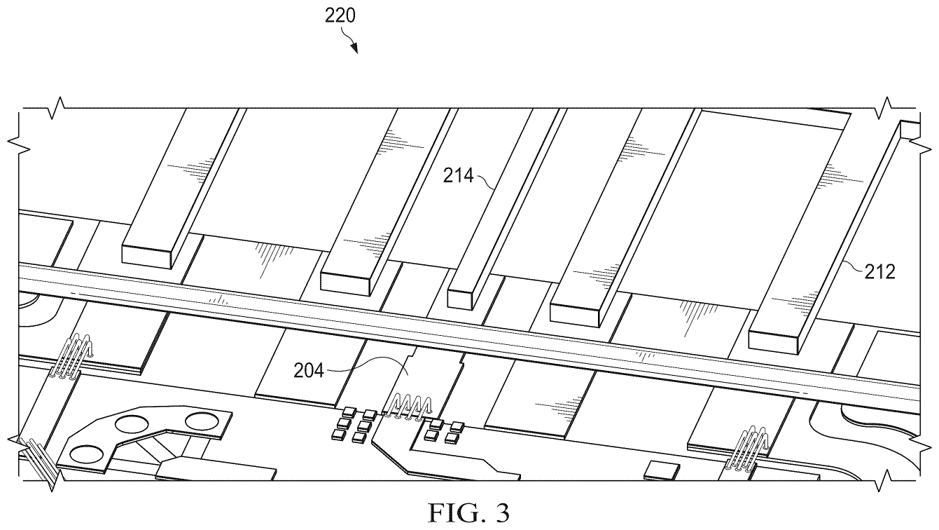

FIG. 3 is a more detailed partial perspective view of a device 220, according to aspects of the present disclosure. The device 220 in this example represents a conventional interconnection of leadframe lead 214 to package trace 204. Conventional techniques involve soldering a leadframe lead 214 to a laminate or ceramic that has a package trace 204 wider than the lead. The device 220 in FIG. 3 is used as a reference for comparison herein.

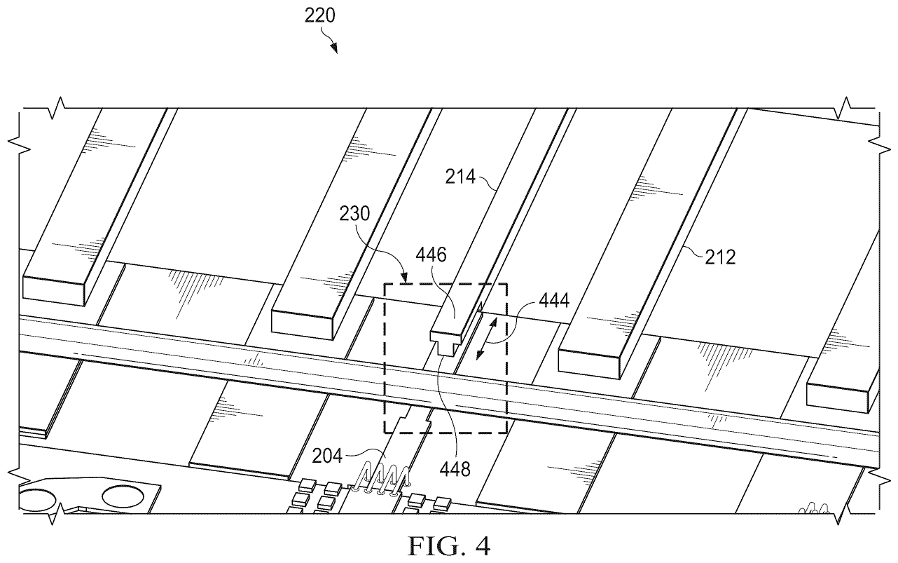

FIG. 4 is a more detailed partial perspective view of a portion of device 220 that may be configured for higher radio frequencies than FIG. 3, according to aspects of the present disclosure. For example, the package trace 204 in FIG. 4 may be narrower than in FIG. 3, being configured for higher radio frequency signals. In order to accommodate the narrower package trace 204, leadframe lead 214 is etched along its base 448 so that the base is narrower than an opposing top surface 446. The leadframe lead 214 is etched along a length, end, or portion 444 proximate the package trace 204. In this example, the leadframe lead 214 along the length 444 forms a “T-shaped” cross section as shown. Lead attach material (e.g., solder) is allowed to fill in around the base 448 of the lead along the length 444. This allows the package trace 204 to be smaller than would otherwise be permitted. Without being bound by theory, maintaining top surface 446 wider than the base surface 448 may allow for providing sufficient current within trace 204 and lead 214. As shown, a longitudinal axis of leadframe lead 214 is generally aligned with a longitudinal axis of its corresponding package trace 204. In an example, spray etching techniques are used for etching leads, such as lead 214.

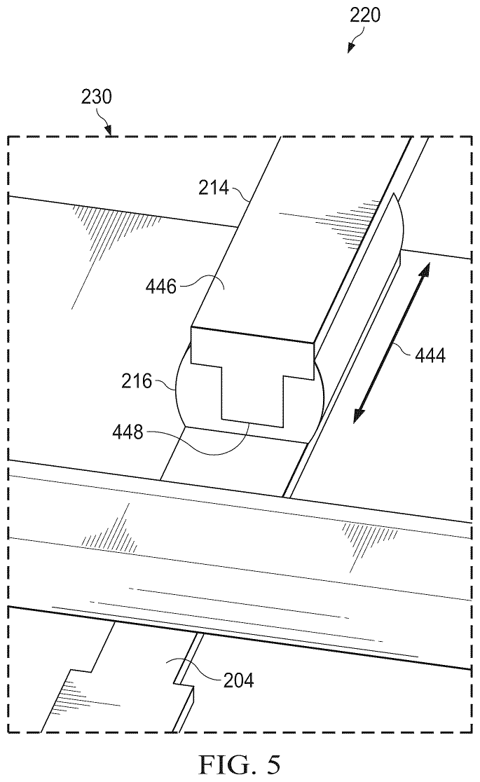

FIG. 5 is an even more detailed partial perspective view of device 220 from FIG. 4 at a stage of manufacture, representing the window 230 as shown in FIG. 4, according to aspects of the present disclosure. In this example, leadframe lead 214 includes a base 448 (or base portion) positioned opposite the package trace 204 and a surface 446 opposing the base 448. Portions of material have been etched away along a length 444 on each side of the base 448 as shown. The length 444 of etched leadframe lead 214 runs about the length of the package trace 204 along which the leadframe lead 214 is connected. In this example, a lead attach material 216 is shown. In some examples, the material 216 includes solder or any other known lead attach material. In some examples, the width of base 448 is less than the width of surface 446, allowing for a higher frequency interconnect between leadframe lead 214 and package trace 204 (such as up to 60 GHz) that is nonetheless capable of supporting robust current flows (such as up to 15 amps). In some examples, the width of the surface 446 may be greater than the width of the package trace 204, further supporting a robust current flow. Another benefit of the leadframe lead 214 configuration is a stronger lead attachment to package trace 204 due to increased surface area for lead attach material to attach to the leadframe lead 214, as compared to the lead 214 in FIG. 3.

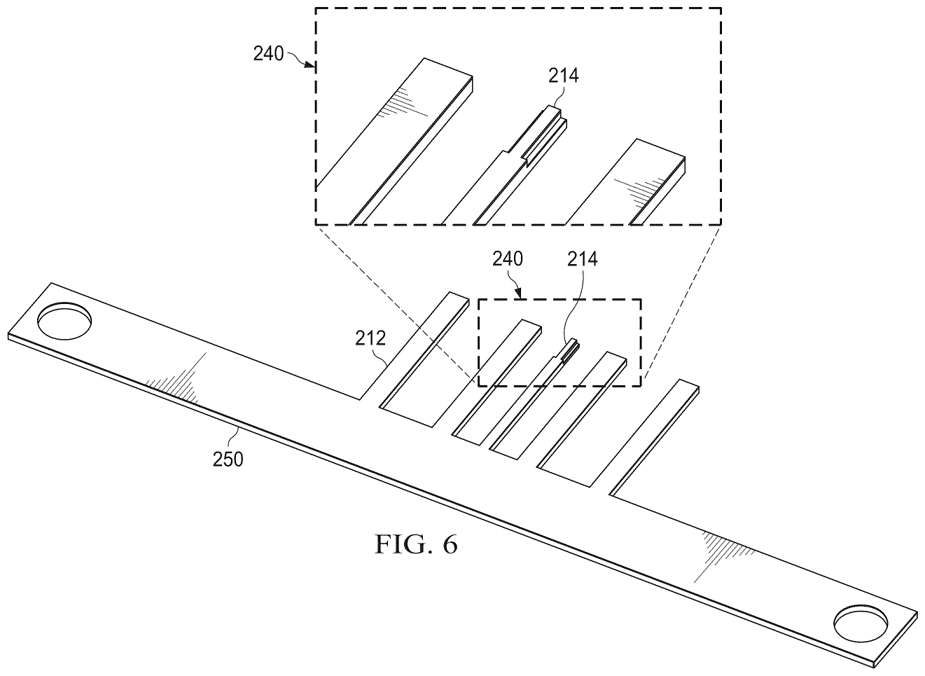

FIG. 6 illustrates two views of leadframe leads 212, according to aspects of the present disclosure. The leads 212 include an underside view of the leadframe lead 214 as shown in FIG. 5. An expanded view according to window 240 is shown. At a stage of manufacture, the tie-bar 250 is removed from the leadframe after attachment, leaving behind the leads on the package.

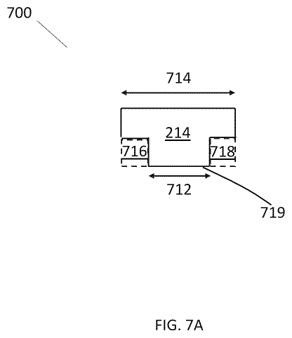

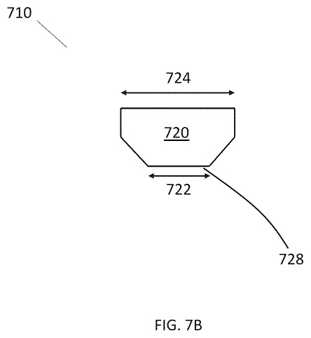

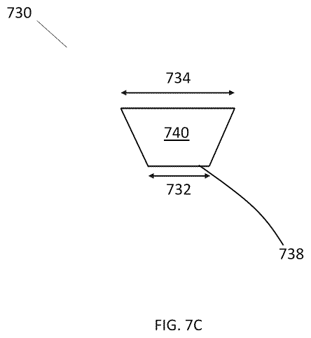

FIGS. 7A-7C are cross-sectional views of different leadframe leads along a length of attachment to package traces, according to aspects of the present disclosure. FIG. 7A illustrates cross-sectional view 700 of leadframe lead 214 as shown in FIGS. 4 and 5. As shown, a width 712 of the base 719 is smaller than the width 714 of an opposing top surface. The base of leadframe lead 214 is configured to be interconnected and adhered to a corresponding package trace, such as the package trace 204 described previously. The areas denoted by 716 and 718 represent areas (in two-dimensions) and volumes of material (in three dimensions) that have been etched away to form the leadframe lead 214 along a length of the lead 214. In some aspects, the lead 214 comprises a vertical portion (e.g., the base of the T-shaped object) and a horizontal portion (e.g., the top of the T-shaped object) as shown. In some examples, the lead 214 has this T-shape along an end portion or length where the lead 214 is connected to a package trace, such as trace 204.

FIG. 7B illustrates a cross-sectional view 710 of another example of a leadframe lead 720. As shown, a width 722 of the base is smaller than the width 724 of an opposing top surface. The base 728 of leadframe lead 720 is configured to be interconnected and adhered to a corresponding package trace, such as the package trace 204 described previously. FIG. 7C illustrates a cross-sectional view 730 of another example of a leadframe lead 740. As shown, a width 732 of the base is smaller than the width 734 of an opposing top surface. The base 738 of leadframe lead 740 is configured to be interconnected and adhered to a corresponding package trace, such as the package trace 204 described previously. As shown, the cross-section 730 of lead 740 is a trapezoid, with the base parallel to the opposing top surface and sides that are not parallel to each other.

Although the bases 719, 728, and 738 are illustrated as flat, the base of a lead is not required to be flat. For example, the base may have a sawtooth-type shape or other non-planar shape and still within the scope of the disclosure because a width of the base still satisfies being smaller than a width of the opposing surface. One of skill in the art would recognize aspects of these different lead cross-sectional shapes 700, 710, and 730 may be combined to create other shapes that are within the scope of the disclosure.

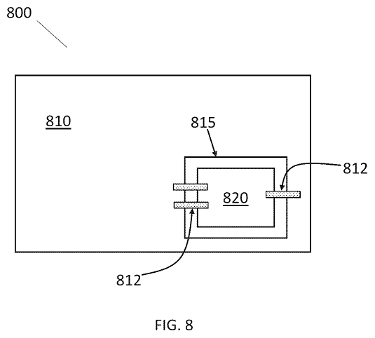

FIG. 8 is an example system 800 including a semiconductor device 820 attached to a circuit board 810, according to aspects of the present disclosure. The semiconductor device 820 may be any of the devices described earlier, such as device 220. In an example, the semiconductor device 820 may be bolted to a metal chassis and leads 812 may be electrically connected to the surrounding circuit board 810. The circuit board 810 may include a cutout 815 for device 820, and the leads 812 may cross the cutout from device 820 to circuit board 810.

Persons skilled in the art will recognize that the apparatus, systems, and methods described above can be modified in various ways. Accordingly, persons of ordinary skill in the art will appreciate that the embodiments encompassed by the present disclosure are not limited to the particular exemplary embodiments described above. In that regard, although illustrative embodiments have been shown and described, a wide range of modification, change, and substitution is contemplated in the foregoing disclosure. It is understood that such variations may be made to the foregoing without departing from the scope of the present disclosure. Accordingly, it is appropriate that the appended claims be construed broadly and in a manner consistent with the present disclosure.

What is claimed is:

1. A semiconductor device comprising:
a semiconductor package comprising a trace;
a leadframe comprising a lead; and
a lead attach material;
wherein the lead comprises a base and an opposing surface opposite the base,
wherein a width of the base is narrower than a width of the opposing surface along a length of the lead, and
wherein the lead attach material is positioned on the base along the length and is configured to connect the lead to the trace.

2. The semiconductor device of claim 1, wherein the lead and the trace are configured to carry a radio frequency signal.

3. The semiconductor device of claim 1, wherein a cross-section of the lead at any position along the length has a T-shape.

4. The semiconductor device of claim 1, wherein a width of the trace is larger than the width of the base of the lead.

5. The semiconductor device of claim 1, wherein the semiconductor device is configured for a radar application.

6. The semiconductor device of claim 1, wherein the leadframe further comprises an additional plurality of leads, and wherein the semiconductor package further comprises an additional plurality of traces.

7. The semiconductor device of claim 1, wherein a width of the base at a position along the lead that does not include the length is the same as a width of the opposing surface at the position.

8. An integrated circuit device for wireless communications comprising:
a package comprising an integrated circuit and a trace;
a frame comprising a lead, wherein the lead comprises a base, a surface opposite the base, and a portion whose length along a longitudinal axis is less than the length of the lead; and
a solder material,
wherein a width of the base is smaller than a width of the surface opposite the base along the portion, and
wherein the lead is electrically connected to the trace via the solder material.

9. The integrated circuit device of claim 8, wherein the lead and the trace are configured to carry a radio frequency signal.

10. The integrated circuit device of claim 8, wherein a width of the trace is larger than the width of the base of the lead.

11. The integrated circuit device of claim 8, wherein a width of the base at a position along the lead that does not include the portion is the same as a width of the surface opposite the base at the position.

12. The integrated circuit device of claim 8, wherein material has been removed from the lead such that the width of the base is smaller than the width of the surface opposite the base along the portion.

13. The integrated circuit device of claim 10, wherein the lead and the trace are configured to carrying radio frequency signals up to 60 GHz.

14. A system comprising:
a circuit board; and
a device connected to the circuit board, the device comprising:
an electronic package comprising a trace;
a leadframe comprising a lead; and
a lead attach material,
wherein the lead comprises a base and an opposing surface opposite the base,
wherein a width of the base is narrower than a width of the opposing surface along a length of the lead, and
wherein the lead attach material is positioned on the base along the length and is configured to connect the lead to the trace.

15. The system of claim 14, wherein the lead and the trace are configured to carry a radio frequency signal.

16. The system of claim 14, wherein a width of the trace is larger than the width of the base of the lead.

17. The system of claim 16, wherein the width of the trace is smaller than the width of the opposing surface of the lead.

18. The system of claim 14, wherein a width of the base at a position along the lead that does not include the length is the same as a width of the opposing surface at the position.

19. The system of claim 14, wherein the leadframe further comprises an additional plurality of leads, and wherein the electrical package further comprises an additional plurality of traces.

20. The system of claim 14, wherein a cross-section of the lead at any position along the length is one of a T-shape or a trapezoid.
